(19) United States
(12) Patent Application Publication
(10) Pub. No.: US 2013/0105801 A1
(43) Pub. Date: May 2, 2013

(54) DISPLAY SUBSTRATE METHOD OF REPAIRING A DISPLAY SUBSTRATE, AND DISPLAY DEVICE INCLUDING THE DISPLAY SUBSTRATE

(71) Applicants: Yul Kyu Lee, Yongin-si (KR); Sun Park, Yongin-si (KR); Joon Hoo Choi, Yongin-si (KR)

(72) Inventors: Yul Kyu Lee, Yongin-si (KR); Sun Park, Yongin-si (KR); Joon Hoo Choi, Yongin-si (KR)

(73) Assignee: Samsung Mobile Display Co., Ltd., Yongin-si (KR)

(21) Appl. No.: 13/448,056

(22) Filed: Apr. 16, 2012

(30) Foreign Application Priority Data
Oct. 28, 2011 (KR) 10-2011-0111481

(51) Int. Cl. H01L 29/786; H01L 21/26

(52) U.S. Cl. 257/59; 257/72; 438/795; 257/E29.273; 257/E21.328

(57) ABSTRACT

Display substrates including a capacitor, methods of repairing a display substrate, and display devices including the display substrate are disclosed. In one embodiment, the capacitor includes a first electrode layer, a dielectric layer, and a second electrode layer sequentially stacked. A portion of the second electrode layer is shorted to the first electrode layer. An opening penetrates the second electrode layer to expose a top surface of the dielectric layer. Due to the opening, the shorted portion is separated from the surrounding portions of the second electrode layer. The opening may be formed by irradiating a laser.

### CROSS-REFERENCE TO RELATED APPLICATIONS

This application relies for priority upon Korean Patent Application No. 10-2011-0111481 filed on Oct. 28, 2011, the contents of which are herein incorporated by reference in its entirety.

### BACKGROUND

1. Field of Disclosure

The described technology generally relates to a display substrate and a method of repairing a display substrate and, more particularly, to a display substrate including a repaired capacitor and a method of repairing a display substrate including a capacitor.

2. Description of the Related Technology

A display device such as an organic electro luminescence display includes a display panel and a display substrate driving the panel. The display substrate includes a plurality of pixel regions. A thin film transistor and a capacitor are disposed in each of the pixel regions.

The capacitor is connected to the thin film transistor for maintaining a data voltage applied to a display layer during each frame period.

The capacitor includes two electrodes opposite to each other and a dielectric layer disposed therebetween. At the time of manufacture, an impurity may be injected into the dielectric layer so that the two electrodes are shorted.

If not repaired, the display substrates are considered defective when the two capacitor electrodes are shorted.

### SUMMARY

One inventive aspect is a display substrate including a repaired capacitor with two electrodes shorted to each other.

Another aspect is a method of repairing a display substrate including a capacitor having two electrodes shorted to each other.

Another aspect is a display substrate which includes: a thin film transistor and a capacitor connected to the thin film transistor. The capacitor includes: a first electrode layer disposed on the base substrate; a second electrode layer disposed on the first electrode and the base substrate, the second electrode layer opposite to the first electrode layer; and a dielectric layer disposed between the first electrode layer and the second electrode layer. The second electrode layer includes a first region shorted to the first electrode layer, and a second region separated from the first region.

In some embodiments, the first region is separated from the second region by an opening exposing at least a top surface of the dielectric layer. A depth of the opening may be greater than a thickness of the second electrode layer.

Another aspect is a method of repairing a display substrate which includes: providing a display substrate including a capacitor having a first electrode layer, a dielectric layer, and a second electrode layer sequentially stacked on a base substrate, a portion of the second electrode layer being shorted to the first electrode layer; and separating the portion of the second electrode layer from at least a portion of the rest portion of the second electrode layer.

The portion of the second electrode layer may be separated from the at least a portion of the rest portion of the second electrode layer by irradiating a laser in a direction from a top of the second electrode layer to the base substrate. The laser may be irradiated to draw a closed loop shape surrounding the portion of the second electrode layer in a plan view. The laser may be irradiated to remove the second electrode layer and a portion of the dielectric layer which are disposed in a proceeding path of the laser until at least a top surface of the dielectric layer is exposed. The portion of the second electrode layer may be separated from the at least a portion of the rest portion of the second electrode layer by forming an opening exposing a top surface of the dielectric layer between the portion of the second electrode layer and at least a portion of the rest portion of the second electrode layer.

### BRIEF DESCRIPTION OF THE DRAWINGS

FIG. 1 is a layout showing an organic electro luminescence display device according to an embodiment.

FIG. 2 is a cross-sectional view taken along a line I-I′ of FIG. 1 to show a display substrate according to an embodiment.

FIG. 3A is a partial plan view showing a capacitor according to an embodiment.

FIG. 3B is a partial cross-sectional view showing a capacitor according to an embodiment.

FIG. 4 is a cross-sectional view showing a display substrate according to another embodiment.

FIG. 5A is a partial plan view showing a capacitor according to another embodiment.

FIG. 5B is a partial cross-sectional view showing a capacitor according to another embodiment.

FIG. 6 is a cross-sectional view showing a display substrate according to still another embodiment.

FIG. 7A is a partial plan view showing a capacitor according to still another embodiment.

FIG. 7B is a partial cross-sectional view showing a capacitor according to still another embodiment.

FIG. 8 is a partial cross-sectional view showing a capacitor according to yet another embodiment.

FIGS. 9A and 9B are cross-section views showing a method of repairing a display substrate according to an embodiment.

### DETAILED DESCRIPTION

Embodiments will now be described more fully hereinafter with reference to the accompanying drawings.

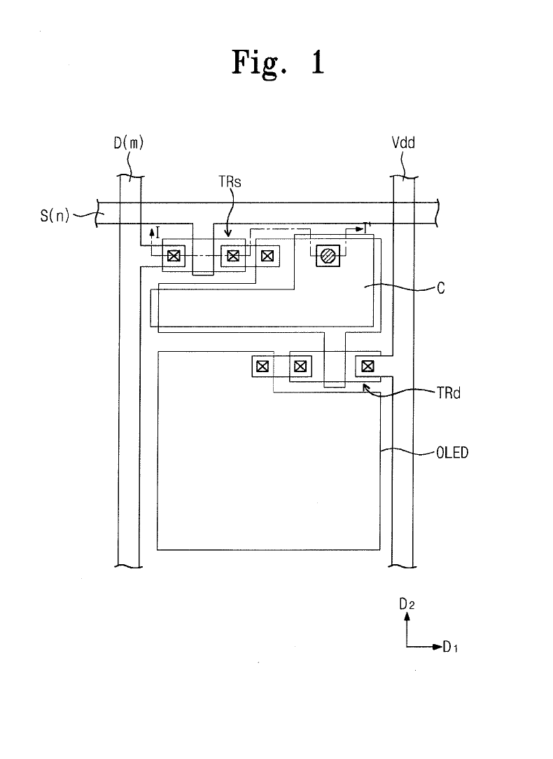

FIG. 1 is a plan view showing one pixel of an organic electro luminescence display device including a display substrate according to an embodiment. The display substrate according to an embodiment may be applied to a liquid crystal display device. However, an organic electro luminescence display device will be described as an example.

Referring to FIG. 1, one pixel of the organic electro luminescence display device may include a scan line S(n), a data line D(m), a power line Vdd, a switching thin film transistor TRs, a driving thin film transistor TRd, a capacitor C, and an organic light emitting diode (OLED).

The scan line S(n) may extend in a first direction D1. The data line D(m) is insulated from the scan line S(n) and crosses the scan line S(n). The data line D(m) may extend in a second direction D2. The power line Vdd may be spaced apart from the data line D(m) and extend in the direction D2.

The switching thin film transistor TRs switches a data signal applied to the data line D(m) according to a signal applied to the scan line S(n). The switching thin film transistor TRs is connected to the driving thin film transistor TRd through the capacitor C to apply the switched data signal to the driving thin film transistor TRd.

The capacitor C is disposed to connect the switching thin film transistor TRs to the driving thin film transistor TRd. The capacitor C stores the data signal applied from the switching thin film transistor TRs for a period of time, so that the data signal may be substantially uniformly applied to the driving thin film transistor TRd even though the switching thin film transistor TRs turns off.

The capacitor C includes a first electrode layer, a second electrode layer, and a dielectric layer. The dielectric layer may contain an impurity, so that a portion of the second electrode layer may be shorted to the first electrode layer. The portion of the second electrode layer is separated from the rest portion of the second electrode layer. This will be described in more detail later.

The driving thin film transistor TRd is connected to the OLED. The driving thin film transistor TRd applies a current to the OLED to induce light emission therefrom.

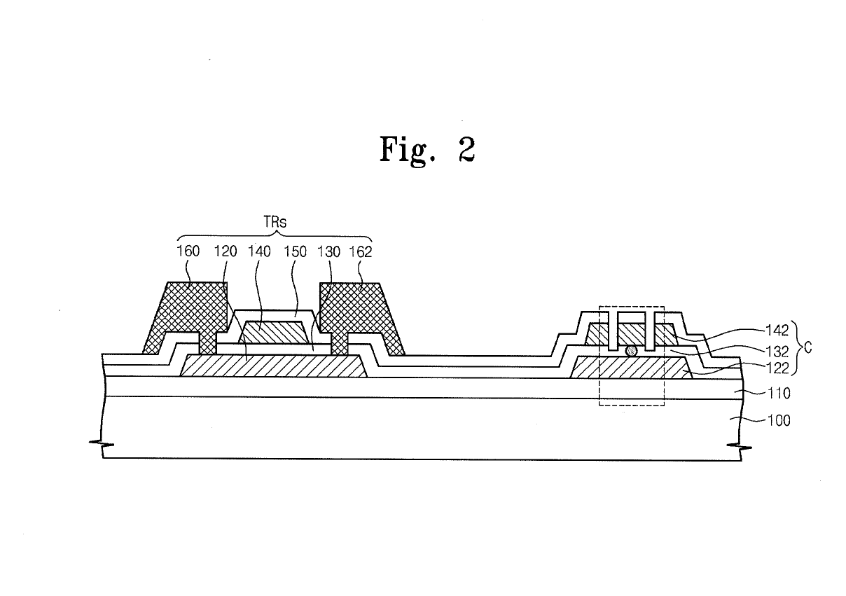

FIG. 2 is a cross-sectional view taken along a line I-I′ of FIG. 1 to show a display substrate according to an embodiment.

The display substrate includes a base substrate 100, a buffer layer 110 disposed on the base substrate 100, the switching thin film transistor TRs disposed on the buffer layer 110, and the capacitor C disposed on the buffer 110.

The switching thin film transistor TRs includes a semiconductor pattern 120, a gate insulating layer 130, a gate electrode 140, an interlayer insulating layer 150, a source electrode 160, and a drain electrode 162.

The semiconductor pattern 120 is disposed on the buffer layer 100 and the base substrate 100. The semiconductor pattern 120 may be formed of poly-silicon or amorphous silicon.

The gate insulating layer 130 is disposed on the semiconductor pattern 120 to cover at least the semiconductor pattern 120. The gate insulating layer 130 may be an insulator such as silicon oxide or silicon nitride. The gate insulating layer 130 may be formed of a plurality of layers.

The gate electrode 140 may be disposed on the gate insulating layer 130 to overlap with at least a portion of the semiconductor pattern 120. The gate electrode 140 may be formed of molybdenum-tungsten (MoW), molybdenum (Mo), tungsten (W), aluminum Al), or any combination thereof.

The interlayer insulating layer 150 is disposed on the gate electrode 140 to cover at least the gate electrode 140. The interlayer insulating layer 150 may be an insulator such as silicon oxide or silicon nitride. The interlayer insulating layer 150 may be formed of a plurality of layers.

The source electrode 160 may be disposed on the interlayer insulating layer 150 to overlap with at least a portion of the semiconductor pattern 120. The source electrode 160 may be connected to a portion of the semiconductor pattern 120 through a contact hole provided in the gate insulating layer 130 and the interlayer insulating layer 150.

The drain electrode 162 is disposed to be spaced apart from the source electrode 160. The drain electrode 162 is disposed on the interlayer insulating layer 150 to overlap with at least a portion of the semiconductor pattern 120. The drain electrode 162 may be connected to a portion of the semiconductor pattern 120 through a contact hole provided in the gate insulating layer 130 and the interlayer insulating layer 150.

The capacitor C includes a first electrode layer 122, a second electrode layer 142, and a dielectric layer 132.

The first electrode layer 122 may be disposed on the same layer as the semiconductor pattern 120. The first electrode layer 122 may be formed of the same material as the semiconductor pattern 120. The first electrode layer 122 and the semiconductor pattern 120 may be formed by the same process.

The second electrode layer 142 is disposed over the first electrode layer 122 to be opposite to the first electrode layer 122. The second electrode layer 142 may be disposed on the same layer as the gate electrode 140. The second electrode layer 142 may be formed of the same material as the gate electrode 140. The second electrode layer 142 and the gate electrode 140 may be formed by the same process.

The dielectric layer 132 is disposed between the first and second electrode layers 122 and 142. The dielectric layer 132 may be formed of at least one of various materials. However, in the present embodiment, the dielectric layer 132 may be formed of the same material as the gate insulating layer 130.

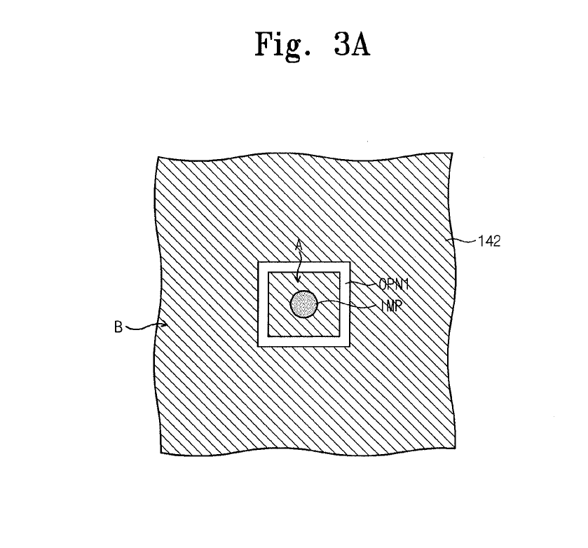

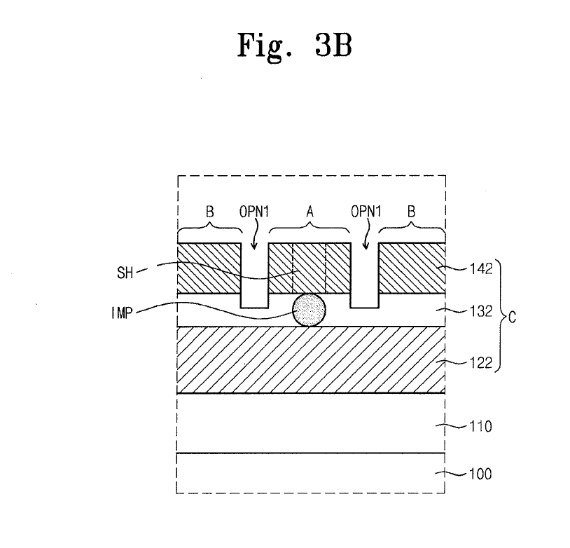

FIG. 3A is a partial plan view showing the capacitor of FIG. 2, and FIG. 3B is a partial cross-sectional view showing the capacitor of FIG. 2.

Referring to FIGS. 3A and 3B, an impurity IMP may be injected into a portion of the dielectric layer 132, so that a portion SH of the second electrode layer 142 may be shorted to the first electrode layer 122.

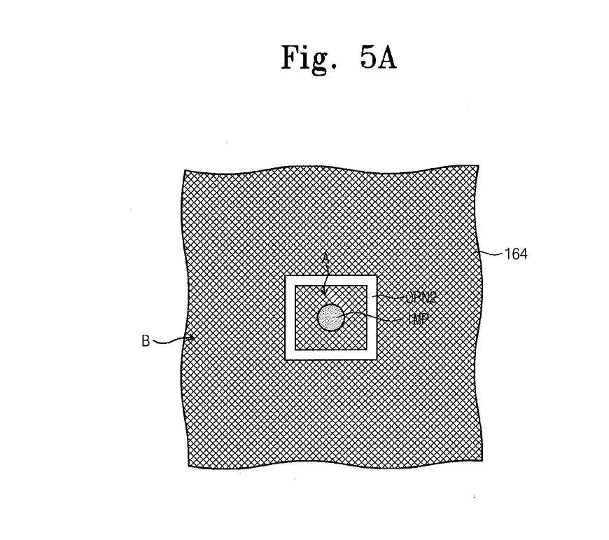

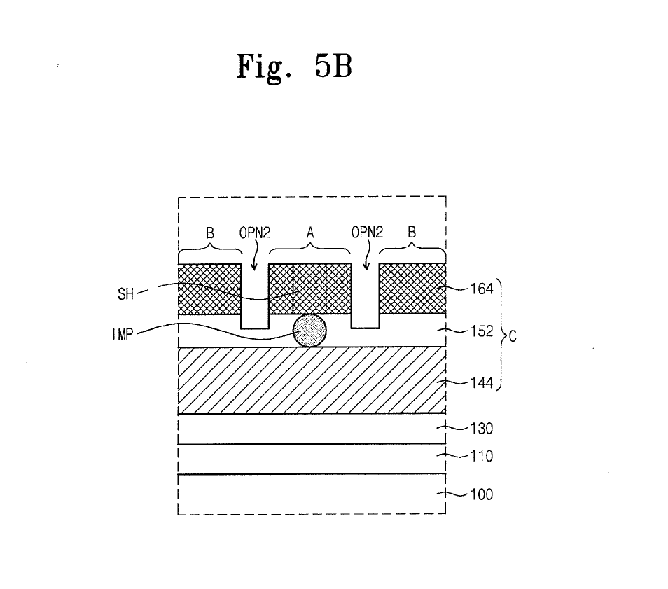

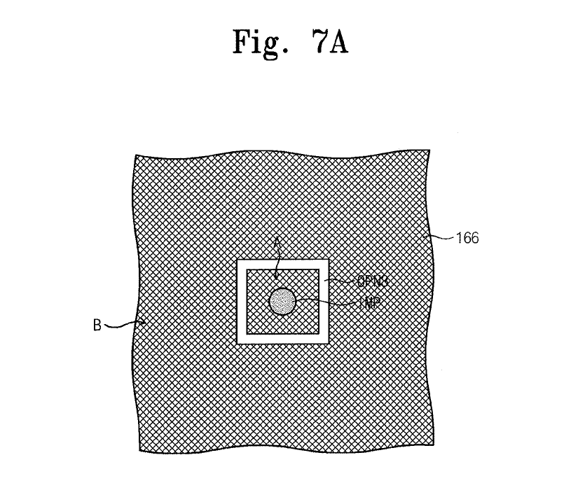

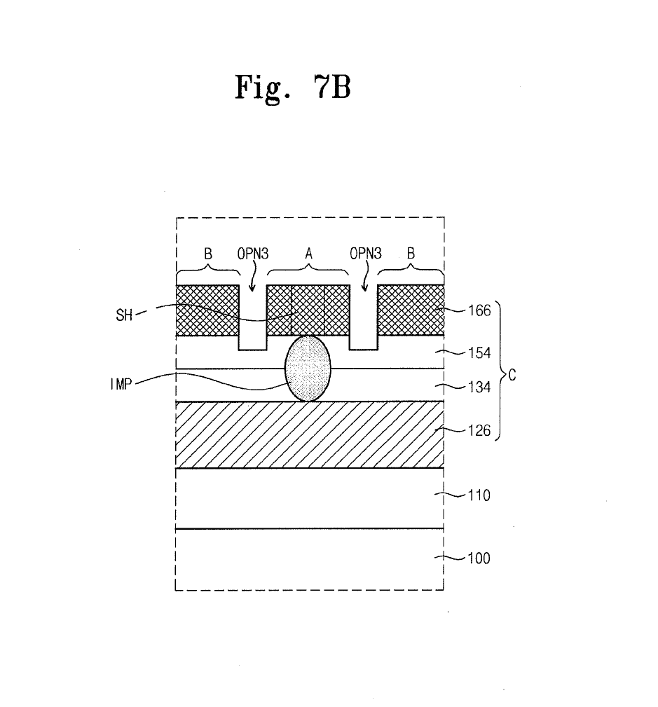

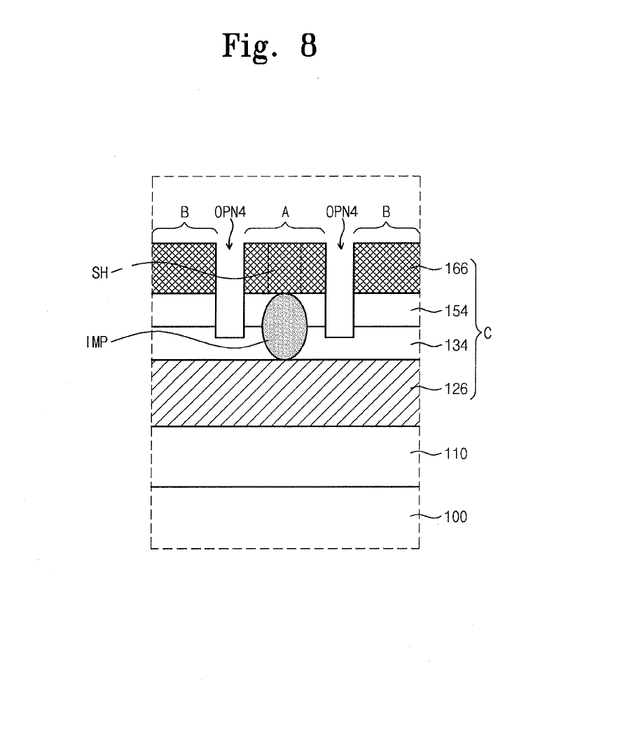

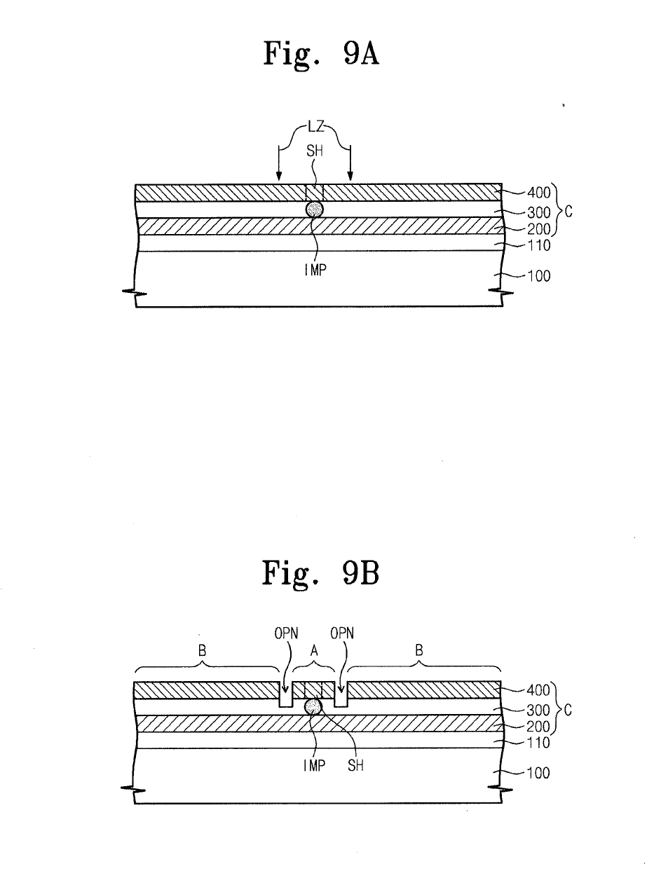

An opening OPN1 may be provided in the second electrode layer 142. The opening OPN1 may be spaced apart from the portion SH of the second electrode layer 142 by a predetermined distance in a direction substantially parallel to the top surface of the base substrate 100. The opening OPN1 may have a closed loop shape surrounding the impurity IMP when viewed from a plan view. The portion SH of the second electrode layer 142 is spaced apart from at least a portion of the rest portion of the second electrode layer 142 by the opening OPN1. The opening OPN1 may be realized in various shapes under a condition that the opening OPN1 has the closed loop shape surrounding the impurity IMP in a plan view. For example, the closed-loop shape of the opening OPN1 may be a circular shape, a quadrangle shape, a triangle shape, an egg shape or other polygonal shapes. This applies to the openings OPN2 (FIG. 5B), OPN3 (FIG. 7B), OPN4 (FIG. 8) and OPN (FIG. 9).

A first region A of the second electrode layer 142 including the portion SH is electrically insulated from a second region B of the second electrode layer 142 except for the first region A by the opening OPN1.

The opening OPN1 penetrates the second electrode layer 142 to expose at least a top surface of the dielectric layer 132. The depth of the opening OPN1 may be greater than the thickness of the second electrode layer 142. In other words, the thickness of a portion of the dielectric layer 132 corresponding to the opening OPN1 may be less than the thickness of the rest portion of the dielectric layer 132.

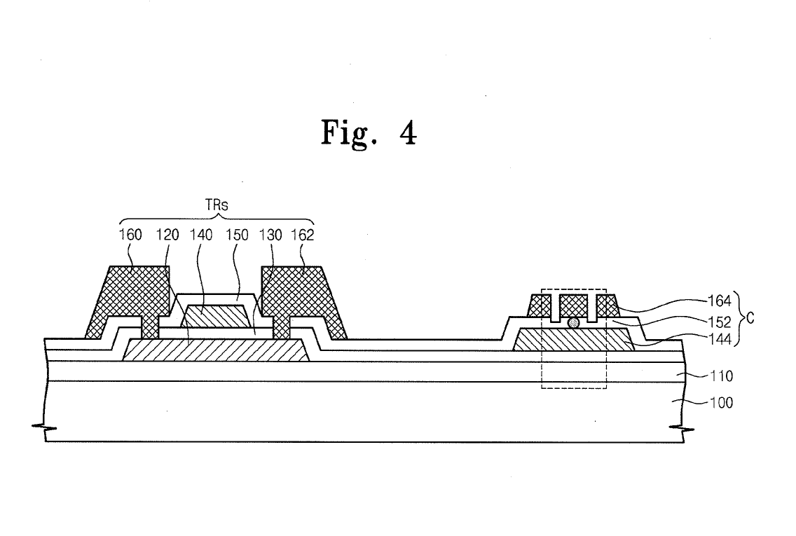

Hereinafter, a display substrate according to another embodiment will be described with reference to FIGS. 4, 5A, and 5B.

FIG. 4 is a cross-sectional view showing a display substrate including a switching thin film transistor TRs and a capacitor C according to another embodiment.

The capacitor C of the display substrate shown in FIG. 4 is different from the capacitor C in FIG. 2. The display substrate shown in FIG. 4 includes the same base substrate 100, the same buffer layer 110, and the same switching thin film transistor TRs as the display substrate in FIG. 2. The capacitor C in FIG. 4 will be described in more detail, hereinafter. In FIG. 4, the same elements as described in the above embodiment in FIG. 2 are indicated by the same reference numerals or the same reference designators and elements similar to those of the above embodiment in FIG. 2 are indicated by similar reference numerals or similar reference designators.

The capacitor C includes a first electrode layer 144, a second electrode layer 164, and a dielectric layer 152.

The first electrode layer 144 may be disposed on the same layer as the gate electrode 140. The first electrode layer 144 may be formed of the same material as the gate electrode 140. The first electrode layer 144 and the gate electrode 140 may be formed by the same process.

The second electrode layer 164 is disposed over the first electrode layer 144 to be opposite to the first electrode layer 144. The second electrode layer 164 may be disposed on the same layer as the source electrode 160 and the drain electrode 162. The second electrode layer 164 may be formed of the same material as the source electrode 160 and the drain electrode 162. The second electrode layer 164, the source electrode 160, and the drain electrode 162 may be formed by the same process.

The dielectric layer 152 is disposed between the first electrode layer 144 and the second electrode layer 164. The dielectric layer 152 may be formed of at least one of various materials. In the present embodiment, the dielectric layer 152 may be formed of the same material as the interlayer insulating layer 150.

FIG. 5A is a partial plan view of a capacitor shown in FIG. 4, and FIG. 5B is a partial cross-sectional view of a capacitor shown in FIG. 4.

Referring to FIGS. 5A and 5B, an impurity IMP may be injected into a portion of the dielectric layer 152, so that a portion SH of the second electrode layer 162 may be shorted to the first electrode layer 144.

An opening OPN2 may be provided in the second electrode layer 164. The opening OPN2 may be spaced apart from the portion SH of the second electrode layer 164 by a predetermined distance in a direction substantially parallel to the top surface of the base substrate 100. The opening OPN2 may have a closed loop shape surrounding the impurity IMP when viewed from a plan view. The portion SH of the second electrode layer 164 is spaced apart from at least a portion of the rest portion of the second electrode layer 164 by the opening OPN2.

A first region A of the second electrode layer 164 including the portion SH is electrically insulated from a second region B of the second electrode layer 164 except the first region A by the opening OPN2.

The opening OPN2 penetrates the second electrode layer 164 to expose at least a top surface of the dielectric layer 152. The depth of the opening OPN2 may be greater than the thickness of the second electrode layer 164. In other words, the thickness of a portion of the dielectric layer 152 corresponding to the opening OPN2 may be less than the thickness of the rest portion of the dielectric layer 152.

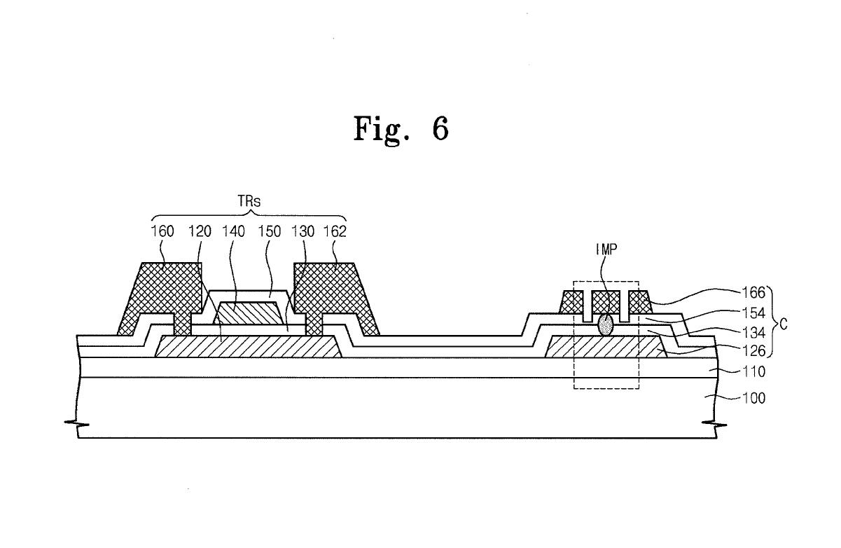

Hereinafter, a display substrate according to still another embodiment will be described with reference to FIGS. 6, 7A, and 7B.

FIG. 6 is a cross-sectional view showing a display substrate including a switching thin film transistor TRs and a capacitor C according to still another embodiment.

The capacitor C of the display substrate shown in FIG. 6 is different from the capacitor C in FIG. 2. The display substrate shown in FIG. 6 includes the same base substrate 100, the same buffer layer 110, and the same switching thin film transistor TRs as the display substrate in FIG. 2. The capacitor C in FIG. 6 will be described in more detail, hereinafter. In FIG. 6, the same elements as described in the above embodiment in FIG. 2 are indicated by the same reference numerals or the same reference designators and elements similar to those of the above embodiment in FIG. 2 are indicated by similar reference numerals or similar reference designators.

The capacitor C includes a first electrode layer 126, a second electrode layer 166, a first dielectric layer 134, and a second dielectric layer 154.

The first electrode layer 126 may be disposed on the same layer as the semiconductor pattern 120. The first electrode layer 126 may be formed of the same material as the semiconductor pattern 120. The first electrode layer 144 and the semiconductor pattern 120 may be formed by the same process.

The second electrode layer 166 is disposed over the first electrode layer 126 to be opposite to the first electrode layer 126. The second electrode layer 166 may be disposed on the same layer as the source electrode 160 and the drain electrode 162. The second electrode layer 166 may be formed of the same material as the source electrode 160 and the drain electrode 162. The second electrode layer 166, the source electrode 160, and the drain electrode 162 may be formed by the same process.

The first dielectric layer 134 is disposed between the first electrode layer 126 and the second electrode layer 166. The first dielectric layer 134 may be formed of at least one of various materials. In the present embodiment, the first dielectric layer 134 may be formed of the same material as the gate insulating layer 130.

The second dielectric layer 154 is disposed between the first and second electrode layers 126 and 166 and is disposed on the first dielectric layer 154. That is, the second dielectric layer 154 is disposed between the first dielectric layer 134 and the second electrode layer 166. The second dielectric layer 154 may be formed of at least one of various materials. In the present embodiment, the second dielectric layer 154 may be formed of the same material as the interlayer insulating layer 150.

FIG. 7A is a partial plan view of a capacitor C shown in FIG. 6, and FIG. 7B is a partial cross-sectional view of a capacitor C shown in FIG. 6.

Referring to FIGS. 7A and 7B, an impurity IMP may be injected into portions of the first and second dielectric layer 134 and 154, so that a portion SH of the second electrode layer 166 may be shorted to the first electrode layer 126.

An opening OPN3 may be provided in the second electrode layer 166. The opening OPN3 may be spaced apart from the portion SH of the second electrode layer 166 by a predetermined distance in a direction substantially parallel to the top surface of the base substrate 100. The opening OPN3 may have a closed loop shape surrounding the impurity IMP when viewed from a plan view. The portion SH of the second electrode layer 166 is spaced apart from at least a portion of the rest portion of the second electrode layer 166 by the opening OPN3.

A first region A of the second electrode layer 166 including the portion SH is electrically insulated from a second region B of the second electrode layer 166 except the first region A by the opening OPN3.

The opening OPN3 penetrates the second electrode layer 166 to expose at least a top surface of the second dielectric layer 154. The depth of the opening OPN3 may be greater than the thickness of the second electrode layer 166. In other words, the thickness of a portion of the second dielectric layer 154 corresponding to the opening OPN3 may be less than the thickness of the rest portion of the second dielectric layer 154.

FIG. 8 is a partial cross-sectional view of a capacitor C according to yet another embodiment.

The capacitor C shown in FIG. 8 may include the same first electrode layer 126, the same electrode layer 166, the same first dielectric layer 134, and the second dielectric layer 154 as the capacitor C shown in FIGS. 6, 7A, and 7B. In the present embodiment, an opening OPN4 will be described in more detail.

In the capacitor C in FIG. 8, the impurity IMP may be injected into portions of the first and second dielectric layer 134 and 154, so that the portion SH of the second electrode layer 166 may be shorted to the first electrode layer 126.

The opening OPN4 may be provided in the second electrode layer 166. The opening OPN4 may be spaced apart from the portion SH of the second electrode layer 166 by a predetermined distance in a direction substantially parallel to the top surface of the base substrate 100. The opening OPN4 may have a closed loop shape surrounding the impurity IMP when viewed from a plan view. The portion SH of the second electrode layer 166 is spaced apart from at least a portion of the rest portion of the second electrode layer 166 by the opening OPN4.

The first region A of the second electrode layer 166 including the portion SH is electrically insulated from the second region B of the second electrode layer 166 except the first region A by the opening OPN4.

The opening OPN4 penetrates the second electrode layer 166 and the second dielectric layer 154 to expose at least a top surface of the first dielectric layer 134. The depth of the opening OPN4 may be greater than the sum of the thickness of the second electrode layer 166 and the thickness of the second dielectric layer 154. In other words, the thickness of a portion of the first dielectric layer 134 corresponding to the opening OPN4 may be less than the thickness of the rest portion of the first dielectric layer 134.

FIGS. 2 to 8 show the display substrates including the capacitors (hereinafter, referred to as ‘top gate capacitors) and the thin film transistors having top gate structures where the gate electrodes are disposed on the semiconductor patterns.

Even though not shown in drawings, a display substrate according to yet still another embodiment may be a display substrate including a capacitor (hereinafter, referred to as ‘a bottom gate capacitor’) and a thin film transistor having a bottom gate structure where a gate electrode is disposed on the semiconductor pattern. A first electrode layer, a second electrode layer, and a dielectric layer of the bottom gate capacitor may include materials different from those of the top gate capacitor, respectively. However, the bottom gate capacitor has a structure including the first electrode layer, the dielectric layer, and the second electrode layer sequentially stacked like the top gate capacitor. Thus, the bottom gate capacitor may be applied with the capacitors having the openings formed in the second electrode layers which are described with reference to FIGS. 2 to 8.

Hereinafter, a method of repairing a display substrate according to an embodiment will be described with reference to FIGS. 9A and 9B. FIGS. 9A and 9B are cross-section views showing a method of repairing a display substrate according to an exemplary embodiment of the present invention.

Referring to FIGS. 9A and 9B, a display substrate includes a capacitor C formed over the buffer layer 110 and the base substrate 100. The capacitor C is formed by sequentially stacking a first electrode layer 200, a dielectric layer 300, and a second electrode layer 400. An impurity IMP may be injected into the dielectric layer 300 in a manufacturing process, so that a portion SH of the second electrode layer 400 may be shorted to the first electrode layer 200.

The portion SH of the second electrode layer 400 is separated from at least a portion of the rest portion of the second electrode layer 400, thereby repairing the display substrate.

For example, an opening OPN (See FIG. 9B) may be formed in the second electrode layer 400. The opening OPN is spaced apart from the portion SH of the second electrode layer 400 by a predetermined distance in a direction substantially parallel to the top surface of the base substrate 100. The opening OPN has a closed loop shape surrounding the impurity IMP when viewed from a plan view. Due to the opening OPN, the portion SH of the second electrode layer 400 is separated from a portion of the rest portion of the second electrode layer 400.

A laser LZ may be irradiated in a direction from a top of the second electrode layer 400 to the base substrate 100 to remove the second electrode layer 400 and a portion of the dielectric layer 300 disposed in a proceeding path of the laser LZ, thereby forming the opening OPN. The laser LZ may be irradiated on the closed loop shape. The opening OPN penetrates the second electrode layer 400 to expose at least a top surface of the dielectric layer 300.

A first region A of the second electrode layer 400 including the portion SH is electrically insulated from a second region B of the second electrode layer 400 except for the first region A by the opening OPN. Thus, the second portion B of the capacitor can be operated normally, and the display substrate including the first and second electrode layers 200 and 300 being shorted to each other can be repaired effectively.

According to at least one of the disclosed embodiments, the display substrate including the capacitor with two electrodes shorted to each other is repaired to normally operate. Thus, it is possible to secure the display substrate of good quality, thereby improving manufacture yield.

While the above embodiments have been described with reference to the accompanying drawings, it will be apparent to those skilled in the art that various changes and modifications may be made without departing from the spirit and scope of the following claims. Therefore, it should be understood that the above embodiments are not limiting, but illustrative.

What is claimed is:

1. A display substrate comprising:
a base substrate including a plurality of pixel regions; and
a thin film transistor and a capacitor electrically connected to the thin film transistor in each of the pixel regions,
wherein the capacitor comprises:
a first electrode layer disposed over the base substrate;
a second electrode layer disposed over the first electrode and the base substrate; and
a dielectric layer disposed between the first and second electrode layers,
wherein the second electrode layer includes a first region shorted to the first electrode layer, and a second region separated from the first region.

2. The display substrate of claim 1, wherein the thin film transistor comprises:
a semiconductor pattern disposed over the base substrate;
a gate electrode disposed over the semiconductor pattern and the base substrate; and
a source electrode and a drain electrode at least one of which is electrically connected to the semiconductor pattern, wherein the source and drain electrodes are spaced apart from each other.

3. The display substrate of claim 2, wherein the first electrode layer is disposed on the same layer as the semiconductor pattern, and
wherein the second electrode layer is disposed on the same layer as the gate electrode.

4. The display substrate of claim 2, wherein the first electrode layer is disposed on the same layer as the gate electrode, and
wherein the second electrode layer is disposed on the same layer as at least one of the source and drain electrodes.

5. The display substrate of claim 2, wherein the first electrode layer is disposed on the same layer as the semiconductor pattern; and
wherein the second electrode layer is disposed on the same layer as at least one of the source and drain electrodes.

6. The display substrate of claim 1, wherein the thin film transistor comprises:
a gate electrode disposed over the base substrate;
a semiconductor pattern disposed over the gate electrode and the base substrate; and
a source electrode and a drain electrode at least one of which is electrically connected to the semiconductor pattern, wherein the source and drain electrodes are spaced apart from each other.

7. The display substrate of claim 1, wherein the first region is separated from the second region by an opening exposing at least a top surface of the dielectric layer.

8. The display substrate of claim 7, wherein the depth of the opening is greater than the thickness of the second electrode layer.

9. The display substrate of claim 1, wherein the dielectric layer includes i) a first dielectric layer disposed on at least the first electrode layer and ii) a second dielectric layer disposed on the first dielectric layer,
wherein the first region is separated from the second region by an opening exposing at least a top surface of the second dielectric layer, and
wherein the depth of the opening is greater than the thickness of the second electrode layer.

10. The display substrate of claim 1, wherein the dielectric layer includes i) a first dielectric layer disposed on at least the first electrode layer and ii) a second dielectric layer disposed on the first dielectric layer,
wherein the first region is separated from the second region by an opening exposing at least a top surface of the first dielectric layer, and
wherein the depth of the opening is greater than the sum of the thickness of the second electrode layer and the thickness of the second dielectric layer.

11. A method of repairing a display substrate, comprising:
providing a display substrate including a capacitor, wherein the capacitor comprises a first electrode layer, a dielectric layer, and a second electrode layer sequentially stacked on a base substrate, wherein the second electrode layer comprises a first portion and a second portion adjacent to the first portion, and wherein the first portion of the second electrode layer is shorted to the first electrode layer; and
separating the first and second portions of the second electrode layer from the remaining portion of the second electrode layer.

12. The method of claim 11, wherein the separating comprises irradiating a laser onto a region bordering the second portion and remaining portion in a direction from a top of the second electrode layer to the base substrate.

13. The method of claim 12, wherein the laser is irradiated to draw a closed loop shape surrounding the first and second portions of the second electrode layer in a plan view.

14. The method of claim 13, wherein the laser is irradiated to remove i) the bordering region of the second electrode layer and ii) a portion of the dielectric layer which is substantially directly below the bordering region until at least a top surface of the dielectric layer is exposed.

15. The method of claim 14, wherein the separating comprises forming an opening which exposes a top surface of the dielectric layer in the bordering region.

16. A display device comprising:
a display layer configured to display an image; and
a display substrate configured to drive the display layer,
wherein the display substrate comprises:
a base substrate including a plurality of pixel regions; and
a thin film transistor and a capacitor electrically connected to the thin film transistor in each of the pixel regions,
wherein the capacitor comprises:
a first electrode layer disposed over the base substrate;
a second electrode layer disposed over the first electrode and the base substrate; and
a dielectric layer disposed between the first and second electrode layers,
wherein the second electrode layer includes a first region shorted to the first electrode layer, and a second region separated from the first region.
